(19) United States
(12) Patent Application Publication
(10) Pub. No.: US 2025/0015776 A1
(43) Pub. Date: Jan. 9, 2025

(54) SURFACE ACOUSTIC WAVE (SAW) STRUCTURES WITH TRANSVERSE MODE SUPPRESSION

(71) Applicant: Qorvo US, Inc., Greensboro, NC (US)

(72) Inventors: Tsuyoshi Yokoyama, Hyogo (JP); Tabito Tanaka, Osaka (JP); Jun Sung Chun, High Point, NC (US)

(21) Appl. No.: 18/888,375

(22) Filed: Sep. 18, 2024

Related U.S. Application Data
(63) Continuation of application No. 17/452,825, filed on Oct. 29, 2021, now Pat. No. 12,143,090.

(51) Int. Cl. H03H 9/02; H03H 9/54; H03H 9/64

(52) U.S. Cl. CPC H03H 9/02015; H03H 9/54; H03H 9/6453

(57) ABSTRACT

Surface acoustic wave (SAW) structures with transverse mode suppression are disclosed. In one aspect, the SAW structure provides digits or fingers with broad interior terminal end shapes. By providing such shapes, spurious modes above the resonance frequency of the SAW are suppressed, thereby providing desired out-of-band rejection that helps satisfy design criteria such as keeping a higher Q value, a higher K2 value, and a better Temperature Coefficient of Frequency (TCF).

### PRIORITY APPLICATION

The present application is a continuation of and claims priority to U.S. patent application Ser. No. 17/452,825, filed Oct. 29, 2021, and entitled “SURFACE ACOUSTIC WAVE (SAW) STRUCTURES WITH TRANSVERSE MODE SUPPRESSION,” the disclosure of which is hereby incorporated herein by reference in its entirety.

### BACKGROUND

### I. Field of the Disclosure

The technology of the disclosure relates generally to surface acoustic waves and ways to reduce transverse modes spurious around resonance frequencies.

### II. Background

Surface acoustic wave (SAW) devices, such as SAW resonators and SAW filters, are used in many applications such as radio frequency (RF) filters. For example, SAW filters are commonly used in Second Generation (2G), Third Generation (3G), and Fourth Generation (4G) wireless transceiver front ends, duplexers, and receive filters. The widespread use of SAW filters is due to, at least in part, that fact that SAW filters exhibit low insertion loss with good rejection, can achieve broad bandwidths, and are a small fraction of the size of traditional cavity and ceramic filters. As with any electronic device, the performance of a SAW device is an important parameter that can impact the overall performance of a system. In this regard, there is a need for a high-performance SAW device. One such solution is a guided SAW device.

Guided SAW devices (i.e., SAW devices having a guided SAW structure) have a layered substrate where a layer of piezoelectric material, which is referred to here as a piezoelectric layer, is bonded or deposited on (e.g., directly on) the surface of a support, or carrier, substrate. As compared to conventional SAW devices, guided SAW devices have an improved quality factor (Q), an improved electromechanical coupling factor (K2), and an improved Temperature Coefficient of Frequency (TCF). However, unwanted spurious modes are typically generated in a guided SAW structure, which hinders a practical use of a guided SAW device. In particular, in a guided SAW device, spurious modes are generated above the resonance frequency of the guided SAW device and, as a result, out-of-band rejection specifications may not be satisfied. Accordingly, there is still a need for improved performance from SAW devices.

### SUMMARY

Aspects disclosed in the detailed description include surface acoustic wave (SAW) structures with transverse mode suppression. In particular, exemplary aspects of the present disclosure provide digits or fingers with broad interior terminal end shapes. By providing such shapes, spurious modes above the resonance frequency of the SAW structure are suppressed thereby providing desired out-of-band rejection that helps satisfy design criteria such as keeping a higher quality factor (Q) value, a higher electromechanical coupling factor (K2) value, and better Temperature coefficient of Frequency (TCF).

In this regard in one aspect, a SAW filter is disclosed. The SAW filter comprises a first interdigitated electrode comprising a first finger. The first finger has a first width along a longitudinal axis of the first finger for a first length and a second width along the longitudinal axis of the first finger for a second length at a terminal end portion of the first finger. The SAW filter also comprises a second interdigitated electrode.

### BRIEF DESCRIPTION OF THE DRAWINGS

FIG. 1A is a side elevational view of a guided surface acoustic wave (SAW) structure;

FIG. 1B is a top plan view of the guided SAW structure of FIG. 1B with apodization of the interdigital structure;

FIG. 2 provides performance graphs for the guided SAW structure of FIGS. 1A and 1B with transverse modes above the resonant frequency highlighted;

FIG. 3A illustrates a guided SAW structure with transverse mode suppression according to an exemplary aspect of the present disclosure;

FIG. 3B illustrates an exemplary finger end used on the interdigital structure to facilitate transverse mode suppression;

FIG. 4 provides performance graphs for the guided SAW structure with wide finger ends of FIGS. 3A and 3B highlighting the suppressed transverse modes;

FIGS. 5A and 5B illustrate how changing a width of a finger end relative to the finger shaft affects a magnitude of a transverse mode;

FIG. 5C illustrates how changing the area of a finger end affects a magnitude of a transverse mode;

FIGS. 6A and 6B illustrate how changing a gap between finger ends affects a magnitude of a transverse mode;

FIGS. 7A and 7B illustrate how changing a crossing gap between fingers affects a magnitude of a transverse mode;

FIG. 8 illustrates various alternate finger ends;

FIGS. 9A and 9B illustrate how changing a substrate thickness may affect a magnitude of a transverse mode; and

FIG. 10 illustrates a top plan view of an alternate guided SAW structure with a chirped wave apodization.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include surface acoustic wave (SAW) structures with transverse mode suppression. In particular, exemplary aspects of the present disclosure provide digits or fingers with broad interior terminal end shapes. By providing such shapes, spurious modes above the resonance frequency of the SAW structure are suppressed thereby providing desired out-of-band rejection that helps satisfy design criteria such as keeping a higher quality factor (Q) value, a higher electromechanical coupling factor (K2) value, and better Temperature Coefficient of Frequency (TCF).

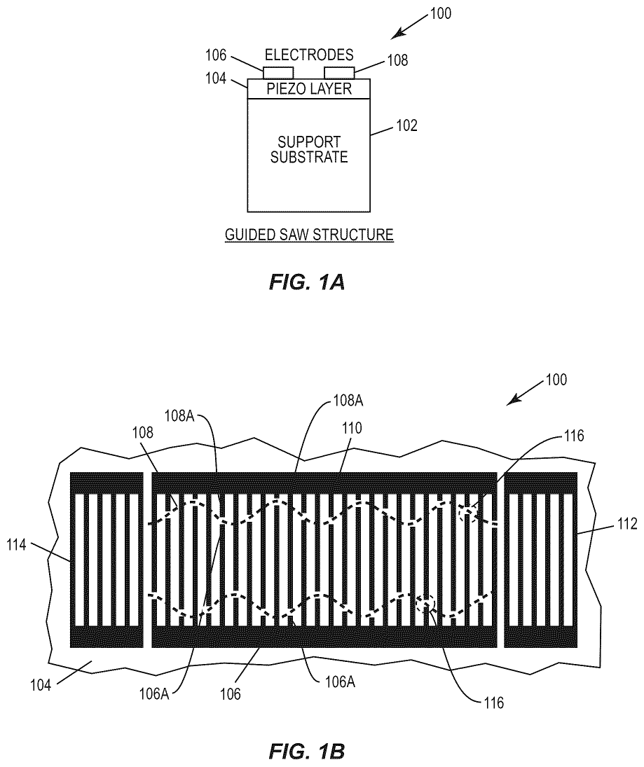

FIGS. 1A and 1B illustrate a conventional guided SAW structure 100 having a support substrate 102 on which a piezoelectric layer 104 is positioned. Interdigitated electrodes 106, 108 are positioned on the piezoelectric layer 104 as better seen in FIG. 1B. The interdigitated electrodes 106, 108 form an interdigital transducer (IDT) 110 with optional reflectors 112, 114. Further, one of the interdigitated electrodes 106, 108 (e.g., electrode 108) may be a dummy electrode.

With continued reference to FIG. 1B, each interdigitated electrode 106, 108 includes a respective plurality of fingers 106A, 108A that are aligned with one another and are separated by gaps 116. The alignment and presence of the gaps 116 provide apodization of the IDT 110.

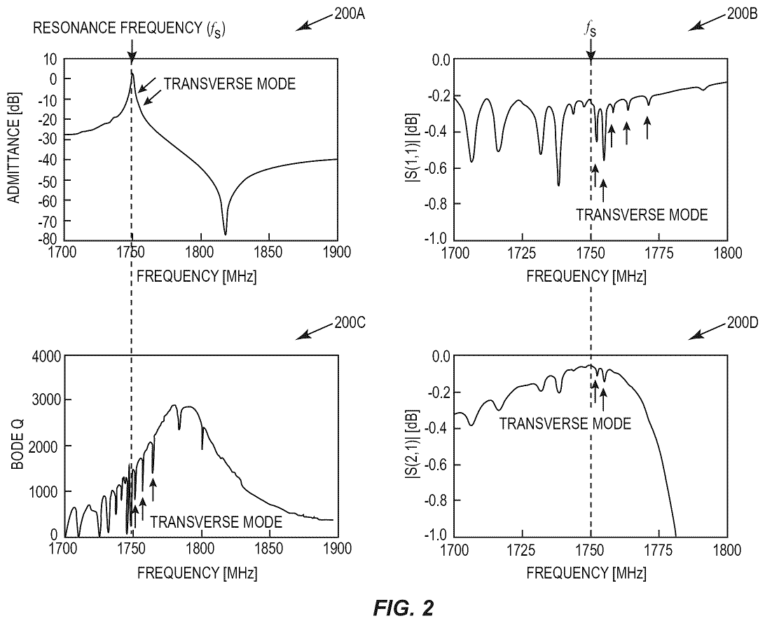

FIG. 2 provides various graphs 200A-200D showing performance of the guided SAW structure 100 against frequency, and particularly shows a resonance frequency fₛ with transverse modes proximate the resonance frequency highlighted. As is readily apparent, while the apodization does some work at suppressing the transverse modes, it is insufficient for some purposes.

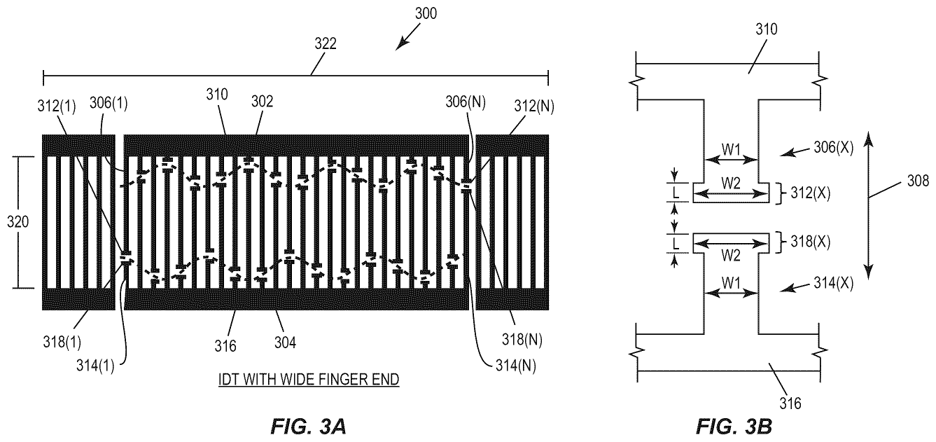

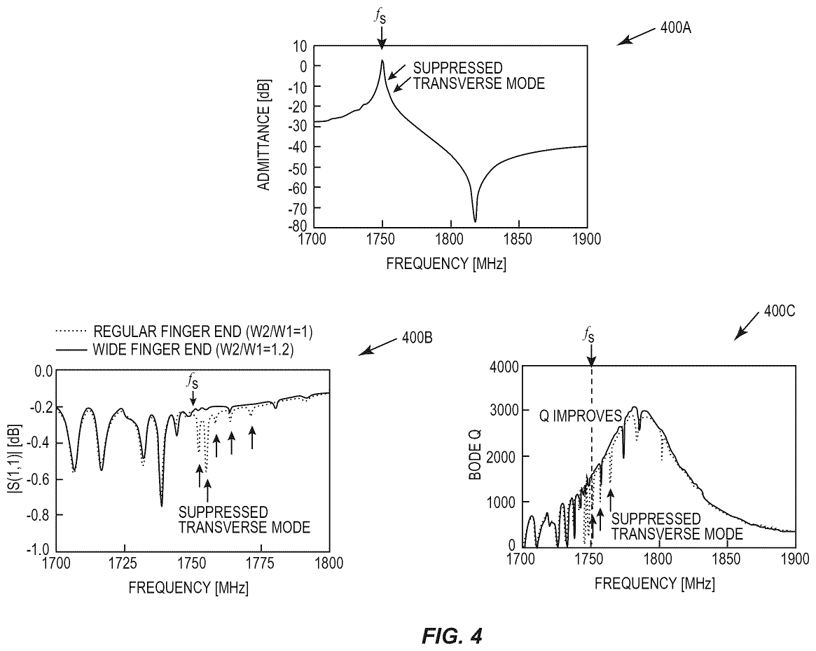

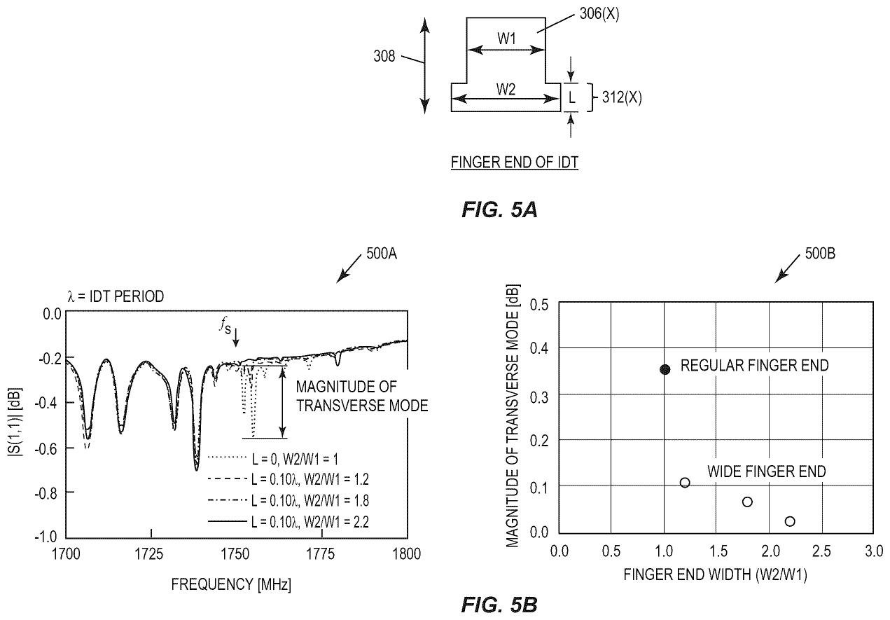

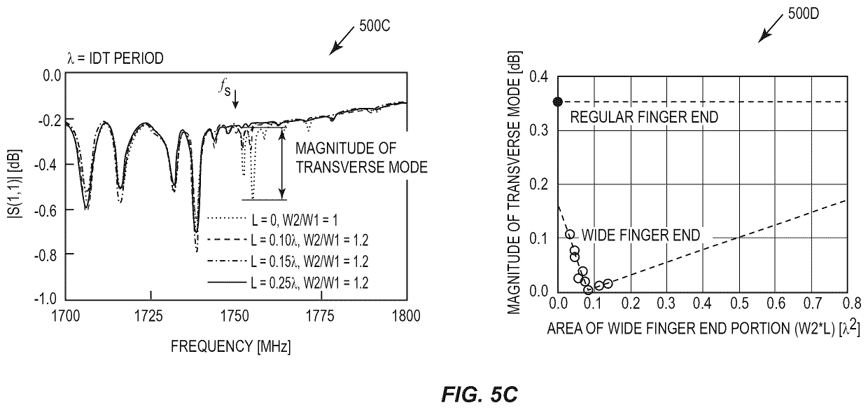

As illustrated in FIGS. 3A and 3B, exemplary aspects of the present disclosure provide a guided SAW filter 300 that includes a first interdigitated electrode 302 and a second interdigitated electrode 304 that are apodized. The first interdigitated electrode 302 has a plurality of fingers 306(1)-306(N) with an exemplary finger 306(X) shown in FIG. 3B. Each of the fingers 306(1)-306(N) has a first width W1 along a longitudinal axis 308 of the fingers 306(1)-306(N). The first width W1 is provided along this longitudinal axis 308 for a first length defined by the distance between a lateral bar 310 and a terminal end portion 312(1)-312(N) of the finger 306(1)-306(N). The terminal end portion 312(1)-312(N) of the finger 306(1)-306(N) has a second width W2 along the longitudinal axis 308 for a second length L (see also FIG. 5A). The apodization is perpendicular to the longitudinal axis 308 and may be described as being along a length direction of the SAW structure 100. Further, the apodization is formed in a wave pattern and may follow a sine or cosine wave pattern.

Similarly, the second interdigitated electrode 304 has a plurality of fingers 314(1)-314(N) with an exemplary finger 314(X) shown in FIG. 3B. Each of the fingers 314(1)-314(N) has a first width W1 along the longitudinal axis 308. The first width W1 is provided along this longitudinal axis 308 for a length defined by the distance between a lateral bar 316 and a terminal end portion 318(1)-318(N) of the finger 314(1)-314(N). The terminal end portion 318(1)-318(N) of the finger 314(1)-314(N) has a second width W2 along the longitudinal axis 308 for a second length L (see also FIG. 5A).

Note that as illustrated, both the fingers 306(1)-306(N) and the fingers 314(1)-314(N) include the wider terminal end portions 312(1)-312(N), 318(1)-318(N). However, the disclosure is not so limited and only one or the other of the fingers 306(1)-306(N) or 314(1)-314(N) may include the wider terminal end portions 312(1)-312(N), 318(1)-318(N). Note further, that as illustrated, the widths W1 of the fingers 306(1)-306(N) are the same as the widths W1 of the fingers 314(1)-314(N), but such identity is not required by the present disclosure and the W1 of fingers 306(1)-306(N) may differ from the W1 of the fingers 314(1)-314(N). Still further, even if both fingers 306(1)-306(N) and 314(1)-314(N) have the wider terminal end portions 312(1)-312(N), 318(1)-318(N), they do not necessarily have to have the same widths W2 relative to each other.

FIG. 4 provides graphs 400A-400C illustrating how the guided SAW filter 300 suppresses the transverse modes. For reference, the wave amplitude of the apodization is 2.42. The aperture 320, length 322, and IDT length/wave were set to 202, 100%, and 10%, respectively. By using the wide finger ends, the transverse modes can be significantly suppressed, and Q also improves. λ is an interdigital transducer (IDT) period of the SAW filter 300.

There are a number of parameters associated with the finger ends that may be optimized to achieve desired transverse mode suppression. FIG. 5A is provided, which merely re-illustrates an exemplary finger 306(X). FIGS. 5B and 5C illustrate the ramifications of two-parameter variations. FIG. 5B illustrates how changing the ratio of W2/W1 will affect how much the transverse mode is suppressed, while FIG. 5C illustrates how changing L and the area of the terminal end portion 312(X) will affect how much the transverse mode is suppressed

In this regard, FIG. 5B shows graphs 500A and 500B with L set to 0.12 and various W2/W1 ratios. Specifically, ratios of 1.2, 1.8, and 2.2 are illustrated, with the transverse mode being increasingly suppressed as the W2/W1 ratio increases. However, if the W2/W1 ratio is too large (i.e., W2 is too wide), there may be bridging to an adjacent finger, so the W2/W1 ratio may have a practical limit of three (3) or less.

FIG. 5C illustrates graphs 500C, 500D showing what happens to transverse mode suppression with changes to L while holding W2/W1 constant. Specifically, L is varied between 0.12, 0.152, and 0.252. The data suggests that the greatest transverse mode suppression occurs around 0.122. Areas larger than this show that the magnitude of the transverse mode slowly increases, and an area greater than approximately 0.722 will obviate any transverse mode suppression. Approximately, as used herein, 2867-2909 means within five percent.

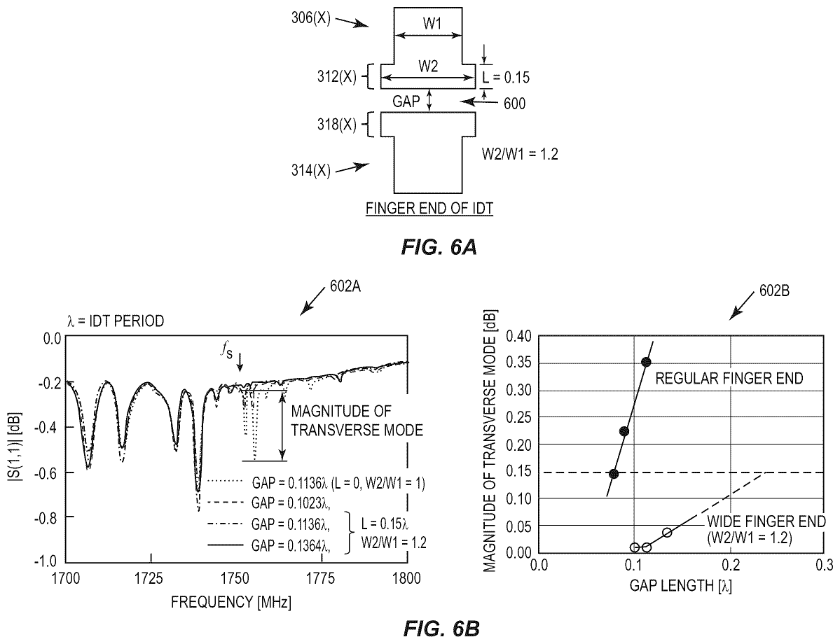

Similarly, a gap 600 illustrated in FIG. 6A between the terminal end portions (e.g., end portions 312(X) and 318(X)) of the fingers 306(X), 314(X) may be varied to achieve varied results. FIG. 6B shows the results of such variation in gap. Specifically, graphs 602A, 602B show how changing the gap from 0.10232, through 0.11362, to 0.13642 while keeping L and W/W2 constant affects the magnitude of the transverse mode. If the gap 600 is 0.242 or less, the wider terminal end portions of the present disclosure provide more effective transverse mode suppression than narrowing the gap of a conventional finger. Note that if the gap is too narrow, it may be difficult to manufacture with current technologies, and accordingly, a gap 600 of more than approximately 0.1 micrometers may be used.

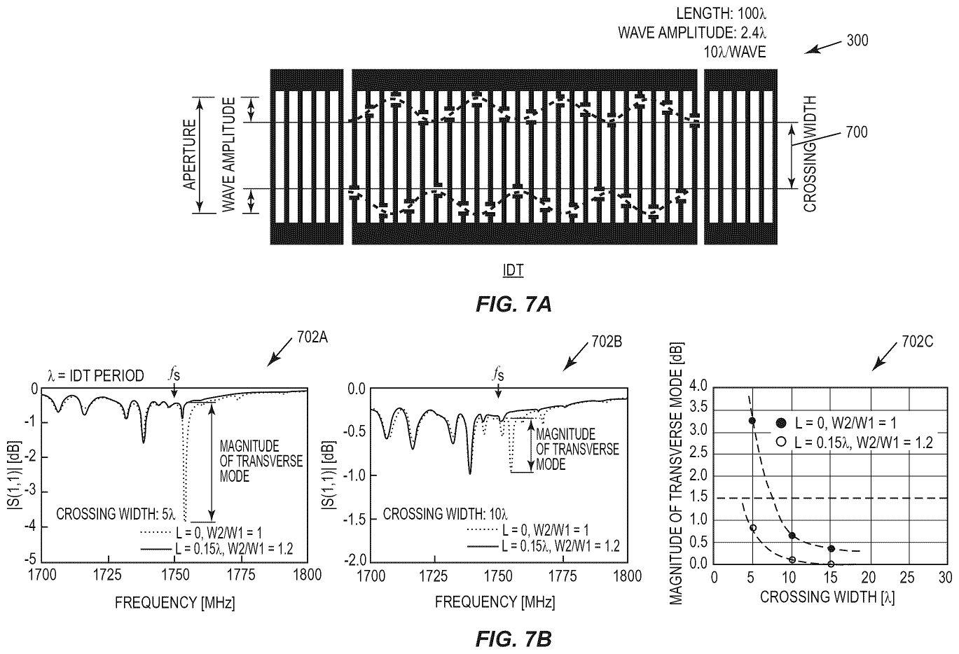

Still another parameter may be a crossing width 700 illustrated in FIG. 7A. FIG. 7B illustrates graphs 702A, 702B, and 702C showing the impact on the transverse mode suppression created by variations in the crossing width 700. Specifically, a crossing width of 5) is shown in graph 702A and a crossing width 700 of 102 is shown in graph 702B. The effect of the wide terminal end portions 312(1)-312(N) and 318(1)-318(N) are greater as the crossing width 700 is smaller. However, if the crossing width 700 is too narrow, the distance between the upper and lower apodization regions are too close, so a crossing width 700 of at least approximately 12 is suggested.

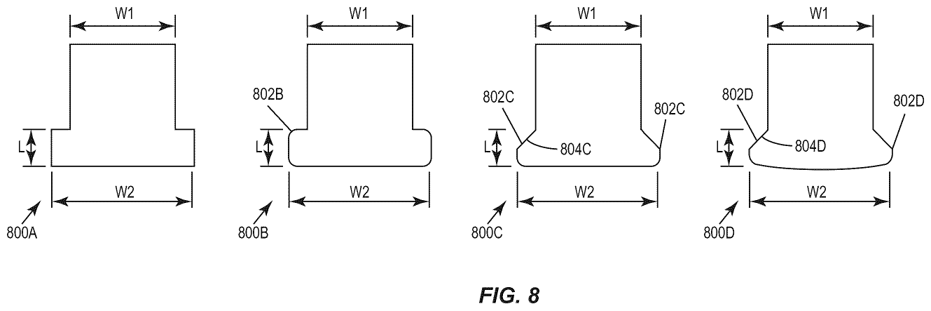

While FIGS. 3A, 5A, 6A, and 7A suggest that the terminal end portions 312(1)-312(N) and 318(1)-318(N) be rectilinear with right angles at the corners, the present disclosure is not so limited. FIG. 8 provides exemplary alternate terminal end portions 800A-800D where terminal end portion 800A is rectilinear as previously illustrated, but terminal end portions 800B-800D include rounded corner portions 802B, 802C, 802D. The precise radius of curvature and the precise angle of slope 804C, 804D is not central to the present disclosure and may be varied without departing from the scope of the present disclosure. Likewise, minor variations that result from process variations during manufacture are intended to be included within the present disclosure.

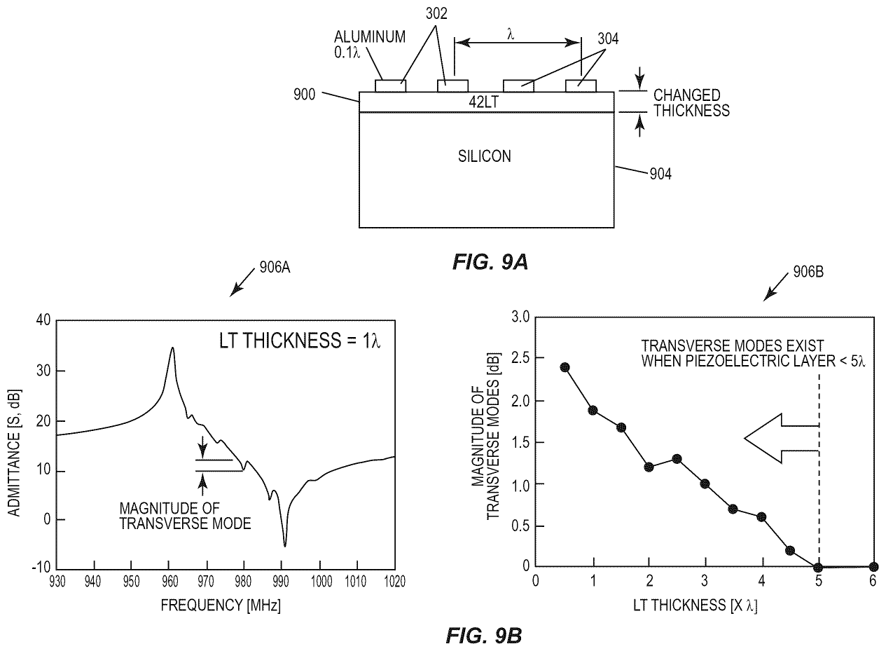

FIGS. 9A and 9B show the impact variations on the thickness (LT) of the piezoelectric material 900 that sits between the interdigitated electrodes 302, 304 and a silicon substrate 904 have on transverse mode suppression. It should be appreciated that the piezoelectric material 900 may be, for example, lithium tantalite or lithium niobite. Likewise, while described as a silicon substrate 904, the substrate may alternatively be sapphire, spinel, quartz, or other ceramics. As shown by graphs 906A and 906B in FIG. 9B, the magnitude of a transverse mode may depend on the thickness of the piezoelectric material 900. When the piezoelectric material 900 is less than 52, transverse modes are seen, and using the wide terminal end portions of the present disclosure may be useful when suppressing transverse modes when LT is less than approximately 52.

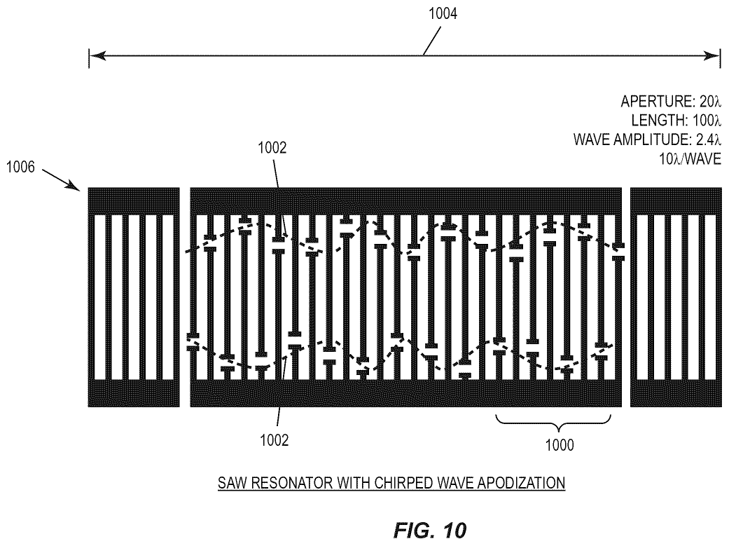

Still another possible variation is to chirp the wave apodization as illustrated in FIG. 10. That is, some portion 1000 of a wave 1002 has a different period than the rest of the wave 1002. In an exemplary aspect, the chirped wave is symmetric about a vertical axis to a length direction 1004 of a SAW filter 1006.

The surface acoustic wave structures with transverse mode suppression according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A method of filtering a signal with a surface acoustic wave (SAW) filter, the method comprising:
passing a signal into a first interdigitated electrode comprising a first plurality of fingers, each finger of the first plurality comprising a substantially uniform first width along a longitudinal axis of the finger for a first length and a second width along the longitudinal axis of the finger for a second length at a terminal end portion of the finger;
exciting a piezoelectric material with the signal only through the first plurality of fingers; and
receiving a filtered signal from the piezoelectric material at all fingers of a second interdigitated electrode comprising a second plurality of second fingers, each second finger of the second plurality comprising a substantially uniform third width along a second longitudinal axis of the second finger for a third length and a fourth width along the second longitudinal axis of the second finger for a fourth length at a second terminal end of the second finger,
wherein each of the first plurality of fingers has a respective opposite one of the second plurality of second fingers, and each pair of first finger and second finger has a gap therebetween.

2. The method of claim 1, wherein passing the signal into the first interdigitated electrode comprises passing the signal into a first electrode that is apodized in a length direction of the SAW filter.

3. The method of claim 1, wherein passing the signal into the first interdigitated electrode comprises passing the signal into a first interdigitated electrode that is apodized with a wave pattern in a length direction of the SAW filter.

4. The method of claim 1, wherein passing the signal into the first interdigitated electrode comprises passing the signal into a first interdigitated electrode wherein the second width is greater than the substantially uniform first width but less than three times the substantially uniform first width.

5. The method of claim 1, wherein passing the signal into the first interdigitated electrode comprises passing the signal into a first interdigitated electrode wherein the second width is greater than the substantially uniform first width by less than 2.5 times the substantially uniform first width.

6. The method of claim 1, wherein passing the signal into the first interdigitated electrode comprises passing the signal into a first interdigitated electrode wherein the terminal end portion of each of the first plurality of fingers has an area corresponding to the second width multiplied by the second length and this area is less than approximately 0.72^{λ}, where λ is an interdigital transducer (IDT) period of the SAW filter.

7. The method of claim 1, wherein passing the signal into the first interdigitated electrode comprises passing the signal into a first interdigitated electrode wherein the terminal end portion of each of the fingers has an area corresponding to the second width multiplied by the second length and this area is less than approximately 0.3λ2, where λ is an interdigital transducer (IDT) period of the SAW filter.

8. The method of claim 1, wherein the gap is between approximately 0.1 micrometers and 0.24λ, where λ is an interdigital transducer (IDT) period of the SAW filter.

9. The method of claim 1, wherein passing the signal into the first interdigitated electrode comprises passing the signal into a first interdigitated electrode wherein the terminal end portion comprises a rounded corner portion.

10. A surface acoustic wave (SAW) filter comprising:
a first interdigitated electrode comprising a first plurality of adjacent fingers, each adjacent finger of the first plurality comprising:
a substantially uniform first width along a longitudinal axis of the adjacent finger for a first length and a second width along the longitudinal axis of the adjacent finger for a second length at a terminal end portion of the adjacent finger; and
a second interdigitated electrode comprising a second plurality of second adjacent fingers, each second adjacent finger of the second plurality comprising:
a substantially uniform third width along a second longitudinal axis of the second adjacent finger for a third length and a fourth width along the second longitudinal axis of the second adjacent finger for a fourth length at a second terminal end of the second adjacent finger;
wherein each of the first plurality of adjacent fingers has a respective opposite one of the second plurality of second adjacent fingers, and each pair of first adjacent fingers and second adjacent fingers has a gap therebetween.

11. A mobile communication device comprising:
a transmitter comprising a surface acoustic wave (SAW) filter comprising:
a first interdigitated electrode comprising a first plurality of adjacent fingers, each adjacent finger of the first plurality comprising:
a substantially uniform first width along a longitudinal axis of the adjacent finger for a first length and a second width along the longitudinal axis of the adjacent finger for a second length at a terminal end portion of the adjacent finger; and
a second interdigitated electrode comprising a second plurality of second adjacent fingers, each second adjacent finger of the second plurality comprising:
a substantially uniform third width along a second longitudinal axis of the second adjacent finger for a third length and a fourth width along the second longitudinal axis of the second adjacent finger for a fourth length at a second terminal end of the second adjacent finger;
wherein each of the first plurality of adjacent fingers has a respective opposite one of the second plurality of second adjacent fingers, and each pair of first adjacent fingers and second adjacent fingers has a gap therebetween.
